(19) United States
(12) Patent Application Publication
(10) Pub. No.: US 2025/0154650 A1
(43) Pub. Date: May 15, 2025

(54) SUBSTRATE PROCESSING APPARATUS

(71) Applicant: EUGENE TECHNOLOGY CO., LTD., Yongin-si (KR)

(72) Inventors: In Soo SON, Hwaseong-si (KR); Chang Hun SHIN, Icheon-si (KR); Chan Yong PARK, Icheon-si (KR); Deog Hwan KIM, Yongin-si (KR); Jae Jun JUNG, Seoul (KR); Si Won RYU, Yongin-si (KR); Chang Min PARK, Seoul (KR); Jae Sun KIM, Seoul (KR); Ki Hoon KIM, Suwon-si (KR); Jong Hoon KIM, Hwaseong-si (KR); Jeong Hyeon KIM, Yongin-si (KR); In Seong HWANG, Yongin-si (KR)

(21) Appl. No.: 18/416,879

(22) Filed: Jan. 18, 2024

(30) Foreign Application Priority Data
Nov. 13, 2023 (KR) 10-2023-0156295

(51) Int. Cl. C23C 16/44; C23C 16/455; C23C 16/458

(52) U.S. Cl. CPC C23C 16/4412; C23C 16/45565; C23C 16/4583

(57) ABSTRACT

Provided is a substrate processing apparatus that performs respectively processes on a plurality of substrates in a plurality of sub chambers. The substrate processing apparatus includes a plurality of sub chambers in which processes are performed on a substrate, respectively, and a common exhaust part connected to the plurality of sub chambers to exhaust the inside of each of the plurality of sub chambers. Each of the plurality of sub chambers includes a substrate support on which the substrate is supported, a shower head provided to face the substrate support and configured to supply a process gas toward the substrate, an exhaust port provided below the substrate support and connected to the common exhaust part, and a flow control part including a cover plate provided along a circumference of the substrate support and configured to adjust an exhaust flow of the process gas to a lower portion of the substrate support.

### CROSS-REFERENCE TO RELATED APPLICATION

This application claims priority to Korean Patent Application No. 10-2023-0156295 filed on Nov. 13, 2023 and all the benefits accruing therefrom under 35 U.S.C. § 119, the contents of which are incorporated by reference in their entirety.

### BACKGROUND

The present disclosure relates to a substrate processing apparatus, and more particularly, to a substrate processing apparatus that performs respectively processes on a plurality of substrates in a plurality of sub chambers.

A substrate processing apparatus may be an apparatus for depositing reaction particles contained in a process gas injected into a processing space by using a chemical vapor deposition (CVD) method or an atomic layer deposition (ALD) method after disposing a substrate to be processed in the processing space and may be classified into a single wafer-type substrate processing apparatus that is capable of performing a processing process on one substrate and a batch-type substrate processing apparatus that is capable of performing a processing process on a plurality of substrates at the same time.

In general, the batch-type substrate processing apparatus may perform the processing process by accommodating a plurality of substrates in multiple stages in a process tube having a vertical structure. In the batch-type substrate processing apparatus, a process gas may not be injected perpendicular to a deposition surface of the substrate, but may be injected laterally to cause a limitation in which a deposition rate varies depending on a distance from an injection nozzle.

In addition, the single wafer-type substrate processing apparatus has an disadvantage of low process yield as the substrate processing apparatus processes only one substrate in a chamber.

Thus, there is a need for a substrate processing apparatus that is capable of improving process yield and achieving uniform processing of the entire substrate.

### SUMMARY

The present disclosure provides a substrate processing apparatus that improves uniform processing on substrates in each sub chamber while commonly exhausting the plurality of sub chambers.

In accordance with an exemplary embodiment, a substrate processing apparatus includes: a plurality of sub chambers in which processes are performed on a substrate, respectively; and a common exhaust part connected to the plurality of sub chambers to exhaust the inside of each of the plurality of sub chambers, wherein each of the plurality of sub chambers includes: a substrate support on which the substrate is supported; a shower head provided to face the substrate support and configured to supply a process gas toward the substrate; an exhaust port provided below the substrate support and connected to the common exhaust part; and a flow control part including a cover plate provided along a circumference of the substrate support and configured to adjust an exhaust flow of the process gas to a lower portion of the substrate support.

The plurality of sub chambers may be disposed to be symmetrical to each other with respect to the common exhaust part.

The exhaust port may extend along the circumference of the substrate support.

The cover plate may be provided on at least a portion of the circumference of the substrate support to correspond to the exhaust port.

The flow control part may further include: a movable plate stacked on the cover plate so as to be movable along a circumferential direction of the substrate support; and a driver configured to move the movable plate on the cover plate.

The driver may be configured to move the movable plate so that an extension length of the cover plate and the movable plate in the circumferential direction of the substrate support varies.

The cover plate may include a through-part, and the movable plate may be configured to adjust an opened area of the cover plate through the through-part.

The movable plate may include an auxiliary through-part that is provided in shape or number different from that of the through-part.

The cover plate may be provided in the form of a ring or arc that surrounds at least a portion of the substrate support, and the movable plate may be provided in the form of an arc that is equal to or less than that of the cover plate.

The common exhaust part may include: a plurality of individual exhaust lines, each of which communicates with the exhaust port of each of the plurality of sub chambers; a combined exhaust line to which the plurality of individual exhaust line; and a vacuum pump connected to the combined exhaust line.

The substrate processing apparatus may further include a substrate transfer part configured to move the substrate between two adjacent sub chambers in a direction crossing a radial direction of the common exhaust part through a communication space between the plurality of sub chambers.

Each of the plurality of sub chambers may further include: a liner configured to define an exhaust space in a lower space within the sub chamber; and an inner liner provided inside the liner to surround an outer surface of the substrate support, wherein the cover plate may be provided between the liner and the inner liner.

An upper end of the inner liner may be higher than an upper end of the liner.

### BRIEF DESCRIPTION OF THE DRAWINGS

Exemplary embodiments can be understood in more detail from the following description taken in conjunction with the accompanying drawings, in which:

FIG. 1 is a schematic view of a substrate processing apparatus in accordance with an exemplary embodiment;

FIG. 2 is a schematic cross-sectional view of the substrate processing apparatus in accordance with an exemplary embodiment;

FIG. 3 is a view of a flow control part in accordance with an exemplary embodiment;

FIG. 4 is a schematic cross-sectional view a driver of the flow control part in accordance with an exemplary embodiment; and

FIG. 5 is a view illustrating a modified example of the flow control part in accordance with an exemplary embodiment.

### DETAILED DESCRIPTION OF EMBODIMENTS

Hereinafter, specific embodiments will be described in more detail with reference to the accompanying drawings. The present inventive concept may, however, be embodied in different forms and should not be construed as limited to the embodiments set forth herein. Rather, these embodiments are provided so that this disclosure will be thorough and complete, and will fully convey the scope of the present inventive concept to those skilled in the art. In the descriptions, the same elements are denoted with the same reference numerals. In the figures, the dimensions of layers and regions are exaggerated for clarity of illustration. Like reference numerals refer to like elements throughout.

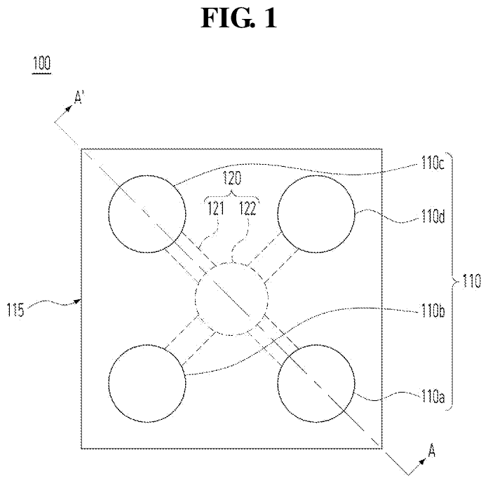

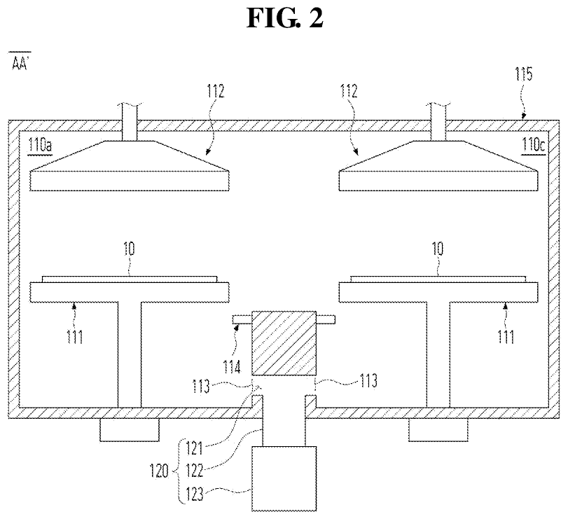

FIG. 1 is a schematic view of a substrate processing apparatus in accordance with an exemplary embodiment, and FIG. 2 is a schematic cross-sectional view of the substrate processing apparatus in accordance with an exemplary embodiment, i.e., a cross-sectional view of the substrate processing apparatus, taken along line A-A′ of FIG. 1.

Referring to FIGS. 1 and 2, a substrate processing apparatus 100 in accordance with an exemplary embodiment may include a plurality of sub chambers 110 each of which is capable of performing a process on a substrate 10, and a common exhaust part 120 connected to the plurality of sub chambers 110 to exhaust the inside of each of the plurality of sub chambers 110.

Each of the plurality of sub chambers 110 may perform the process on the substrate 10. Here, the process may be independently performed to respectively perform the processes on the plurality of substrates 10.

The common exhaust part 120 may be connected to the plurality of sub chambers 110, may communicate with an internal space (or process space) of each of the plurality of sub chambers 110, and may commonly exhaust the insides of the plurality of sub chambers 110 all at once (or at the same time).

Here, each of the plurality of sub chambers 110 may include a substrate support 111 on which the substrate 10 is supported, a shower head 112 provided to be opposite to the substrate support 111 so as to supply the process gas toward the substrate 10, an exhaust port 113 provided below the substrate support 111 and connected to the common exhaust part 120, and a cover plate 114a provided along a circumference of the substrate support 111 and may further include a flow control part 114 that controls an exhaust flow of the process gas to the lower portion of the substrate support 111. The substrate support 111 may support the substrate 10 to be processed, and substrate processing such as deposition may be performed by injecting the process gas onto the substrate 10 supported on the substrate support 111. These substrate support 111 may be provided in each of the plurality of sub chambers 110, through which the plurality of sub chambers 110 respectively perform the processes on each substrate 10.

The shower head 112 may be provided to be opposite to the substrate support 111, may supply the process gas toward the substrate 10, and inject the process gas for processing the substrate onto the substrate 10. Here, the process gas may include a source gas S, a reactant gas R that reacts with the source gas, a source purge gas SP, and a reactive purge gas RP. The source gas S may include titanium tetrachloride (TiCl₄), dichlorosilane DCS (SiH₂Cl₂), etc. In addition, the reactant gas R may react with the source gas, may be different from the source gas, and may include ammonia (NH₃), hydrogen (H₂), etc. In addition, the source purge gas SP may purge the source gas, the reactant purge gas RP may purge the reactant gas, and each of the source purge gas and the reactant purge gas may be an inert gas and include nitrogen (N₂), hydrogen (H₂), and argon (Ar), etc., but is not particularly limited thereto. Here, the source purge gas and the reactant purge gas may be the same or different types of gas, and at least their functions and supply (or injection) order depending on the functions may be different. The source purge gas and the reactant purge gas may be different in at least one of an injection amount, an injection pressure, or an injection speed depending on their functions, but all the injection amount, the injection pressure, and the injection speed may be the same.

The exhaust port 113 may be provided below the substrate support 111 and may be connected to the common exhaust part 120, through which the process gas remaining in each sub chamber 110 is exhausted. Here, the exhaust port 113 may be disposed to be biased (or tilted) to one side in each sub chamber 110 so as to be connected to the common exhaust part 120. In this case, an exhaust flow at a portion (or side) at which the exhaust port 113 is disposed may be relatively stronger that that of the other portion.

The flow control part 114 may control the exhaust flow of the process gas to the lower portion of the substrate support part 111, may allow the exhaust flow of the process gas to the lower portion to be uniform around the entire circumference of the substrate support part 111, and may include a cover plate 114a provided to extend along the circumference of the substrate support 111. The cover plate 114a may be provided to extend along the circumference of the substrate support 111 and may at least partially block and interrupt the exhaust flow of the process gas to the lower portion of the substrate support 111 through the circumference of the substrate support 111.

For example, the cover plate 114a may be provided in a ring, half ring, or arc shape that surrounds at least a portion of the substrate support 111. As a result, the exhaust flow of the process gas toward the cover plate 114a may be blocked, and the process gas may be prevented from escaping directly into the lower portion of the substrate support 111. Here, when the cover plate 114a is provided in the ring shape, at least a portion of the cover plate 114a may be opened to smoothly exhaust the process gas.

Thus, in the substrate processing apparatus 100 in accordance with an exemplary embodiment, the flow control part 114 including the cover plate 114a extending along the circumference of the substrate support 111 may be provided in each of the plurality of sub chambers 110 to adjust the exhaust flow of the process gas to the exhaust port 113 below the substrate support 111. Thus, the processing of each substrate 10 may be uniform, and when the deposition process is performed, a deposition thickness may be uniform throughout the substrate 10 for each sub chamber 110.

Here, the plurality of sub chambers 110 may be disposed symmetrically about the common exhaust part 120. For example, the plurality of sub chambers 110 may include a first sub chamber 110a, a second sub chamber 110b, a third sub chamber 110c, and a fourth sub chamber 110d in which the processes are performed independently. Here, the first sub chamber 110a, the second sub chamber 110b, the third sub chamber 110c, and the fourth sub chamber 110d may be spatially separated (or isolated) by partition walls or the like or may be divided (only) regionally within a chamber wall 115 so that each process is performed independently, to constitute a chamber module (or multi-station chamber). For example, as illustrated in FIGS. 1 and 2, the first sub chamber 110a, second sub chamber 110b, third sub chamber 110c, and fourth sub chamber 110d may be divided only regionally within the chamber wall 230 to communicate with each other, but may not be spatially separated by the partition walls, etc.

The processes may be performed independently in the first sub chamber 110a, the second sub chamber 110b, the third sub chamber 110c, and the fourth sub chamber 110d, may have the same configuration as the shower head 112 and the substrate support 111, and may be numbered in terms of locations (or areas).

In addition, the common exhaust part 120 may be disposed between the first sub chamber 110a, the second sub chamber 110b, the third sub chamber 110c, and the fourth sub chamber 110d. For example, the first sub chamber 110a, the second sub chamber 110b, the third sub chamber 110c, and the fourth sub chamber 110d may be provided in the form of a 2×2 matrix (or square shape) or in a (regular) rhombus shape, and the common exhaust part 120 may be provided (or disposed) at (or between) a center thereof. As the plurality of sub chambers 110 are disposed symmetrically around the common exhaust part 120, uniform suction force (or exhaust flow) may be provided (or applied) to the plurality of sub chambers 110 through the common exhaust part 120.

In addition, the exhaust port 113 may be disposed to extend along the circumference of the substrate support 111, and a length (or width) in the extending direction (or a circumferential direction of the substrate support) may be longer (greater) than a length (or height) in an up and down direction (vertical direction). For example, due to the common exhaust part 120 provided at the center (or between) the plurality of sub chambers 110, each exhaust port 113 may be biased (or tilted) to one side toward the common exhaust part 120, and the exhaust port 113 may be provided laterally so that the process gas is well exhausted (or inhaled) from an opposite portion (side) and may be provided to be elongated in the circumferential direction of the substrate support 111 so that the exhaust flow (or suction force) is maximally uniform in the circumferential direction of the substrate support 111. That is, the exhaust port 113 may extend in a direction toward the common exhaust part 120 and in a direction crossing a downward direction (or vertical direction). Thus, the uniform suction force (or exhaust flow) may be provided (or applied) along the circumference of the substrate support 111 to suppress or prevent differences in exhaust flow (or suction force) depending on the location depending on a distance from the exhaust port 113 from occurring, and the exhaust flow may be uniform throughout the entire circumference of the substrate support portion 111.

Here, the cover plate 114a may be provided on at least a portion of the circumference of the substrate support 111 corresponding to the exhaust port 113. For example, the cover plate 114a may be provided between the substrate support 111 and the chamber wall 115 to correspond to the exhaust port 113. In the cover plate 114a, when the exhaust port 113 is disposed be biased to one side in each sub chamber 110, the exhaust flow at the side (or direction) at which the exhaust port 113 is disposed may be relatively stronger than that at the other side. Thus, a difference in exhaust flow may occur in the circumferential direction of the substrate supporter 111, and thus, the process gas may be not uniformly provided to the entire surface of the substrate 10, and substrate processing may not be uniform. Thus, the cover plate 114a may be provided to correspond to the exhaust port 113, and thus, a flow of the process gas may be diverted to restrict (or weaken) the exhaust flow at the side at which the exhaust port 113 is provided. As a result, the exhaust flow of the process gas may be uniform around the entire circumference of the substrate support part 111.

Here, the cover plate 114a may be provided on at least a portion of the circumference of the substrate support 111 and may be provided in the arc shape on a portion of the circumference of the substrate support 111 to cover (only) an upper portion of the exhaust port 113. When provided in the ring shape around the entire circumference of the substrate supporter 111, a through-part 14a such as a hole may be defined to correspond to the position of the exhaust port 113. When the cover plate 114a is provided in the arc shape on (only) a portion of the circumference of the substrate support 111, a length of the (circular) arc of the cover plate 114a may be equal to that of the exhaust port 113 in the extension direction and greater than an extending length of the exhaust port 113.

Thus, in the substrate processing apparatus 100 in accordance with an exemplary embodiment, even when the exhaust port 113 of each sub chamber 110 is tilted to one side due to the common exhaustion of the plurality of sub chambers 110 through the common exhaust part 120, the exhaust flow of the process gas to the lower portion of the substrate support 111 may be adjusted through the flow control part 114 so that the exhaust flow of the process gas is uniform around the entire circumference of the substrate support 111. As a result, the process gas may be uniformly provided to the entire surface of the substrate 10 so that the entire substrate 10 is processed uniformly, and a thickness (or thin film thickness) of the entire substrate 10 may be made uniform.

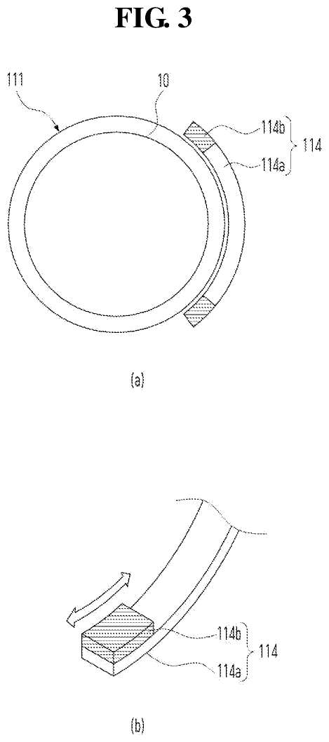

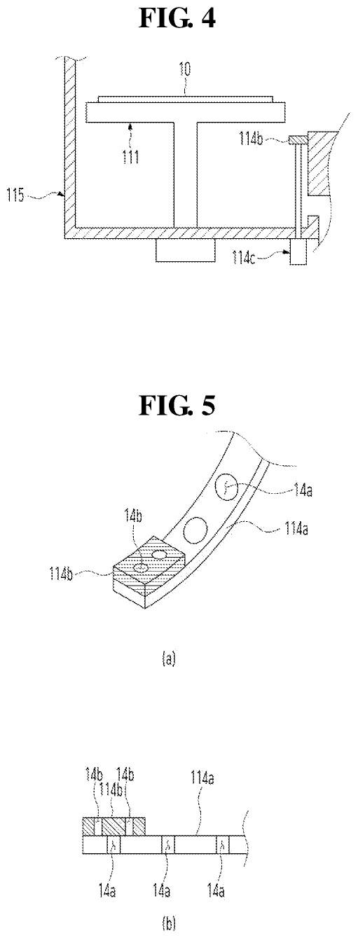

FIG. 3 is a view of a flow control part in accordance with an exemplary embodiment. Here, (a) of FIG. 3 is a plan view of the substrate support and the flow control part, and (b) of FIG. 3 is a schematic perspective view illustrating stacking of a cover plate and a movable plate. FIG. 4 is a schematic cross-sectional view illustrating a driver of the flow control part in accordance with an exemplary embodiment.

Referring to FIGS. 3 and 4, the flow control part 114 may further include a movable plate 114b that is stacked on the cover plate 114a to move along the circumferential direction of the substrate support 111, and a driver 114c that moves the movable plate 114b on the cover plate 114a. The movable plate 114b may be stacked on the cover plate 114a to move along the circumferential direction of the substrate support 111, and while moving on the cover plate 114a, the movable plate 114b may be deviated at least partially from the cover plate 114a to elongate the entire length (i.e., length of the (circular) arc defined by the cover plate and the movable plate) or cover the through-part 14a of the cover plate 114a.

The driver 114c may move the movable plate 114b on the cover plate 114a and be connected to the movable plate 114b through a shaft or the like to move automatically the movable plate through a motor or cylinder. As a result, the movable plate 114b may move to an in-situ without opening and/or venting the sub chamber 110.

For example, the driver 114c may move the movable plate 114b to change an extension length of the cover plate 114a and the movable plate 114b in the circumferential direction of the substrate support 111. The driver 114c may move the movable plate so that at least a portion of the movable plate 114b is deviated from the cover plate 114a, and thus, the length of the (circular) arc defined by the cover plate 114a and the movable plate 114b may be longer by the deviated length than that of the arc of the cover plate 114a, and the extension length of the cover plate 114a and the movable plate 114b in the circumferential direction of the substrate supporter 111 (or the length of the (circular) arc defined by the cover plate and the movable plate) may vary.

The extension length of the cover plate 114a and the movable plate 114b in the circumferential direction of the substrate support 111 may vary through the driver 114c, a range (or area) in which the exhaust flow is restricted (or blocks) may increase or decrease, and the exhaust flow of the process gas along the circumference (or the entire circumference) of the substrate supporter 111 may be adjusted.

FIG. 5 is a view illustrating a modified example of the flow control part in accordance with an exemplary embodiment. Here, (a) of FIG. 5 is a schematic perspective view of the cover plate and the movable plate, and (b) of FIG. 5 is a schematic cross-sectional view of the cover plate and the movable plate.

Referring to FIG. 5, the cover plate 114a may include at least one through-part 14a. The through-part 14a may be defined in the cover plate 114a and may be provided as a single opening in the form of a slit extending along the extension direction of the cover plate 114a or may be provided as a plurality of openings in the cover plate 114a so as to be arranged along the extension direction of the cover plate 114a. The process gas may pass through the through-part 14a, an opened area of the cover plate 114a may be determined depending on a size and number of the through-part 14a, and the exhaust flow of the process gas may be changed depending on the opened area of the cover plate 114a. For example, as the opened area of the cover plate 114a increases, the exhaust flow of the process gas at the portion at which the cover plate 114a is provided may become stronger, and as the opened area of the cover plate 114a becomes smaller, the exhaust flow of the process gas at the portion at which the cover plate 114a is provided may become weaker. As a result, the exhaust flow of the process gas at the portion at which the cover plate 114a is provided and the portion at which the cover plate 114a is not provided may be uniform (or the same).

Here, the movable plate 114b may adjust the opened area of the cover plate 114a through the through-part 14a. The movable plate 114b may block at least a portion of the through-part 14a while moving along the cover plate 114a on the cover plate 114a by the driver 114c and may adjust the opened area of the cover plate 114a, through which the process gas passes, through the through-part 14a. That is, the movable plate 114b may at least partially open and close (or switch) the through-part 14a to adjust the opened area of the cover plate 114a, through which the process gas passes. As a result, the exhaust flow of the process gas may be adjusted at the portion at which the cover plate 114a is provided. For example, the movable plate 114b may change the number and/or area of the through-part 14a that is not blocked (or is blocked) to adjust the opened area of the cover plate 114a, through which the process gas passes due to the unblocking.

The movable plate 114b may include at least one auxiliary through-part 14b that is different in shape and/or number from the through-part 14a. The auxiliary through-part 14b may be defined in the movable plate 114b and may be provided as a single opening in the form of a slit extending along the extension direction of the movable plate 114b or be provided as a plurality of auxiliary through-parts 14b so as to be arranged along the extension direction of the movable plate 114b. In addition, the auxiliary through-part 14b may be different in shape (e.g., size, shape, or spacing, etc.) when compared to the through-part 14a. If the shape of the auxiliary through-part 14b is the same as the through-part 14a, the auxiliary through-part 14b and the through-part 14a may overlap each other to cause a situation in which the movable plate 114b does not cover the through-part 14a. Thus, there is a limit to adjust the opened area of the cover plate 114a by the movable plate 114b. The number of auxiliary through-parts 14b may cause a limitation if the length of the movable plate 114b is similar (or identical) to the length of the cover plate 114a. In case in which the length of the movable plate 114b and the length of the cover plate (114a) are similar to each other, when the number of auxiliary through-parts 14b is equal to the number of through-parts 14a, a spacing of the auxiliary through-part 14b becomes similar to a spacing of the through-part 14a, and also, like the case in which the shape of the auxiliary through-part 14b is the same as the through-part 14a, there may be a limitation to adjust the opened area of the cover plate 114a by the movable plate 114b. For example, the auxiliary through-parts 14b may be defined in smaller numbers than the through-parts 14a, and an opened area per unit area may be smaller than that of the through-parts 14a.

Thus, the shape and/or number of auxiliary through-parts 14b may be changed to easily adjust the opened area of the cover plate 114a, and the opened area of the cover plate 114a may be changed as the movable plate 114b moves.

Here, the movable plate 114b may be provided in the same or shorter arc shape as the cover plate 114a. If the movable plate 114b is longer than the cover plate 114a, the movable plate 114b may block the exhaust flow of the process gas, and thus, even if the movable plate 114b moves, the extension length of each of the cover plate 114a and the movable plate 114b and/or the blocked area of the exhaust flow of the process gas may not be changed. Thus, the movable plate 114b may be provided in the arc shape that is equal to or shorter than the cover plate 114a, and then, while moving the movable plate 114b, the extension length of each of the cover plate 114a and the movable plate 114b may be adjusted as the movable plate 114b moves, and the blocked area of the exhaust flow of the process gas by the cover plate 114a and the movable plate 114b may be adjusted. Here, the movable plate 114b may be shorter than the cover plate 114a. As a result, the movable plate 114b may be provided in plurality at both sides of the cover plate 114a and be symmetrical to each other with respect to the exhaust port 113, and thus, the extension length of each of the cover plate 114a and the movable plate 114b and/or the blocked area of the exhaust flow of the process gas by the cover plate 114a and the movable plate 114b may be adjusted. Thus, it may be easy to form the uniform exhaust flow of the process gas around the entire circumference of the substrate support 111. In addition, the common exhaust part 120 may include a plurality of individual exhaust lines 121, each of which communicates with the exhaust port 113 of each of the plurality of sub chambers 110, and a combined exhaust line 122 to which the plurality of individual exhaust lines 121 are connected, and a vacuum pump 123 connected to the combined exhaust line 122. The plurality of individual exhaust lines 121 may be connected to communicate with the exhaust ports 113 of the plurality of sub chambers 110, respectively, and may extend to the combined exhaust line 122 and then be combined at the combined exhaust line 122 to communicate with each other. For example, the plurality of individual exhaust lines 121 may extend in a straight line (horizontally) from the exhaust port 113 of each of the plurality of sub chambers 110 toward the center (or central portion) of the plurality of sub chambers 110, and all the plurality of individual exhaust lines 121 may be connected to the combined exhaust line 122 to communicate with each other.

The combined exhaust line 122 may be connected to communicate with the plurality of individual exhaust lines 121, may extend in a direction crossing the extension direction of the plurality of individual exhaust lines 121, and may be connected to the vacuum pump 123. Here, a width (or diameter) of the combined exhaust line 122 may be larger than a width (or diameter) of each of the plurality of individual exhaust lines 121, and thus, even if the process gas exhausted from each of the plurality of individual exhaust lines 121 is added, the process gas may be smoothly exhausted. For example, the combined exhaust line 122 may extend in the vertical direction (e.g., downward) and be connected to the vacuum pump 123 in a straight line, and thus, the process gas may be smoothly exhausted through the combined exhaust line 122. In addition, the combined exhaust line 122 may be provided (or disposed) in a direction perpendicular to the extension direction of the plurality of individual exhaust lines 121, and thus, suction force (or vacuum pressure) by the vacuum pump 123 may be uniformly distributed to the plurality of individual exhaust lines 121.

The vacuum pump 123 may be connected to the combined exhaust line 122 to provide a vacuum pressure (or suction force) to the combined exhaust line 122 and the plurality of individual exhaust lines 121 and also may exhaust the process gas remaining in each of the plurality of sub chambers 110 to the outside through the vacuum pressure. For example, the process gas having a predetermined flow rate may be individually supplied to each of the plurality of sub chambers 110 through each shower head 112, and the exhaust of the process gas with respect to the plurality of sub chambers 110 may be performed by one vacuum pump 123. Here, an internal pressure of each sub chamber 110 may vary due to a difference in exhaust performance by each shower head 112 and the vacuum pump 123, and in this case, the movable plate 114b of each sub chamber 110 may move independently, and thus, the difference in internal pressure between the plurality of sub chambers 110 may be reduced or removed.

In addition, since the vacuum pump 123 is commonly used (or commonly provided) with respect to the plurality of sub chambers 110, the exhaust may be biased toward the common exhaust part 120 (i.e., the combined exhaust line and/or the plurality of individual exhaust lines) of the center of the plurality of sub chambers 110 (i.e., the center of the substrate processing apparatus), and thus, the exhaust flow of the process gas may be concentrated toward the vacuum pump 123. In this case, the (internal) pressure of the exhaust flow at the portion at which the exhaust port 113 is disposed (or the exhaust port-side) may be lower than that at the other portion (or an opposite side of the exhaust port), and thus, even in the inside of each of the plurality of sub chambers 110, a pressure distribution in which one side (the exhaust port-side) has a (relatively) low pressure, and the other side (the opposite side) has a (relatively) high pressure may occur. Particularly, the pressure distribution within each sub chamber 110 may occur more unevenly in the circumferential direction of the substrate support 111 to cause a deviation in deposition rate, etc. depending on the location on the entire surface of the substrate 10, and it may be difficult to uniformly process the substrate 10. Here, the exhaust flow of the process gas to the lower portion of the substrate support 111 in the circumferential direction of the substrate support 111 may be adjusted through the flow control part 114 to provide the uniform pressure distribution in the circumferential direction of the substrate support 111 within each of the sub chambers 110, and thus, the uniform processing may be performed on the entire surface of the substrate 10.

The substrate processing apparatus 100 in accordance with an exemplary embodiment may further include a substrate transfer part (not shown) that moves the substrate 10 between two adjacent sub chambers 110 in a direction crossing the radial direction of the common exhaust part 120 through a communication space between the plurality of sub chamber 110.

The substrate transfer part (not shown) may be provided on an upper portion of the common exhaust part 120 and may transfer the substrate 10 between the adjacent two sub chambers 110 in a direction (for example, circumferential direction) crossing the radial direction of the common exhaust part 120 through the communication space between the plurality of sub chambers 110. For example, the substrate transfer part (not shown) may include a rotary shaft (not shown) that axially rotates at an upper portion of the common exhaust part 120, and a plurality of holders (not shown), each of which extends radially from the rotary shaft (not shown). The rotary shaft (not shown) may be provided in a direction perpendicular to a vertical direction at the upper portion of the common exhaust part 120 to axially rotate with respect to the common exhaust part 120 and also may allow each of the plurality of holders (not shown) to rotate (move) in a direction crossing an extension direction of each holder (not shown).

Each of the plurality of holders (not shown) may extend in a radial direction from the rotary shaft (not shown) and may move in a direction (or circumferential direction) crossing the extension direction (or radial direction) in accordance with the axial direction of the rotary shaft (not shown) so that the substrate 10 moves between two adjacent sub chambers 110 in the direction crossing the radial direction of the common exhaust part 120. For example, the plurality of holders (not shown) may be provided in the same number as the plurality of sub chambers 110, and one substrate 10 may be supported on each holder (not shown) and then be transferred to each sub chamber 110. Here, the plurality of sub chambers 110 may communicate with each other through the communication space and constitute a multi-station chamber, and the communication space may be a path through which the substrate 10 supported on each holder (not shown) moves to the adjacent sub chamber 110.

Each of the plurality of sub chambers 110 may further include a liner (not shown) defining an exhaust space in a lower space within the sub chamber 110, and an inner liner (not shown) provided inside the liner (not shown) to surround an outer surface of the substrate support 111. The liner (not shown) may be provided in the lower space within the sub chamber 110 to define (or limit) the exhaust space between the sub chamber 110 and the substrate support 111. Here, the exhaust space may refer to a (lower) space in which the process gas or process by-products, etc., which do not react on the substrate 10, are escaped from the substrate 10, and thus, the process gas or process by-products may be exhausted from the exhaust space to the common exhaust part 120 through the exhaust port 113. Here, the substrate 10 may be provided, and the process gas may react so that the (upper) space in which the substrate processing is actually performed, may be referred to as a process space in contrast to the exhaust space. For example, the liner (not shown) may be erected on a bottom surface of the chamber wall 115, may be provided along an inner surface of the chamber wall 115, and may be spaced apart from the substrate support 111 so as to be disposed around (circumference) of the substrate support 111 or surround (wrap) the substrate support 111. Here, the exhaust port 113 may be provided in the liner (not shown).

An inner liner (not shown) may be provided inside the liner (not shown) (or between the substrate support and the liner) to surround the outer surface of the substrate support 111 and define the exhaust space (or exhaust passage) having the ring shape along the circumference of the substrate support 111 between the liner (not shown) and the inner liner (not shown). In addition, the inner liner (not shown) may be provided along a circumference (or around) the substrate support 111, may surround (or wrap) the substrate support 111, and may surround the outer surface of the substrate support 111 to protect the substrate support 111 against the process gas, etc.

Here, the cover plate 114a may be provided between the liner (not shown) and the inner liner (not shown). The cover plate 114a may be provided between the liner (not shown) and the inner liner (not shown) to effectively block the exhaust flow of the process gas at the provided portion, adjust the exhaust flow of the process gas for each position of the exhaust space in accordance with the opened area through the cover plate 114a, and allow the exhaust flow of the process gas to be uniform around the entire circumference of the substrate support 111.

Here, an upper end of the inner liner (not shown) may be higher than that of the liner (not shown). When the upper end of the inner liner (not shown) is disposed below the upper end of the liner (not shown), the process gas, etc. may be exhausted downward to be introduced between the inner liner (not shown) and the substrate support 111, and thus, the substrate support 111 may be damaged and/or contaminated by the process gas, etc. However, when the upper end of the inner liner (not shown) is higher than the upper end of the liner (not shown), the process gas may not be introduced between the inner liner (not shown) and the substrate support 111 due to the position that is deviated from the substrate support 111 and the direction in which the vacuum pressure (or suction force) acts and thus may be fully introduced into the exhaust space between the liner (not shown) and the inner liner (not shown), in which the vacuum pressure directly acts. Thus, effective exhaustion of the process gas, etc. may be achieved.

In addition, the upper end of the inner liner (not shown) may be provided higher than the upper end of the liner (not shown) and be disposed around a top surface of the substrate support 111 and/or a circumference of the substrate 10 to generate a flow (e.g. laminar flow) of the process gas parallel to the (processing) surface of the substrate 10. Here, the position (or height) relationship between the upper end of the inner liner (not shown) and the top surface of the substrate support 111 may be adjusted by elevating the substrate support 111 through the elevation part.

As described above, in the present disclosure, a flow control part including the cover plate extending along the circumference of the substrate support may be provided in each of the plurality of sub chambers to control the exhaust flow of the process gas to the exhaust port below the substrate support, and thus, the processing for each substrate may be uniform, and when performing the deposition process, the deposition thickness may be uniform across the entire substrate in each sub chamber. In addition, even when the exhaust port of each sub chamber is tilted to one side due to the common exhaust for the plurality of sub chambers, the exhaust flow of the process gas to the lower portion of the substrate support may be adjusted through the flow control part so that the uniform exhaust flow of the process gas is generated around the entire circumference of the substrate support, and thus, since the process gas is uniformly provided to the entire surface of the substrate, the entire substrate may be processed uniformly, and the deposition having the uniform thickness may be achieved.

In the substrate processing apparatus in accordance with the exemplary embodiment, a flow control part including the cover plate extending along the circumference of the substrate support may be provided in each of the plurality of sub chambers to control the exhaust flow of the process gas to the exhaust port below the substrate support, and thus, the processing for each substrate may be uniform, and when performing the deposition process, the deposition thickness may be uniform across the entire substrate in each sub chamber.

In addition, even when the exhaust port of each sub chamber is tilted to one side due to the common exhaust for the plurality of sub chambers, the exhaust flow of the process gas to the lower portion of the substrate support may be adjusted through the flow control part so that the uniform exhaust flow of the process gas is generated around the entire circumference of the substrate support, and thus, since the process gas is uniformly provided to the entire surface of the substrate, the entire substrate may be processed uniformly, and the deposition having the uniform thickness may be achieved.

Although embodiments have been described with reference to a number of illustrative embodiments thereof, the embodiments are not limited to the foregoing embodiments, and thus, it should be understood that numerous other modifications and embodiments can be devised by those skilled in the art that will fall within the spirit and scope of the principles of this disclosure. Hence, the real protective scope of the present inventive concept shall be determined by the technical scope of the accompanying claims.

What is claimed is:

1. A substrate processing apparatus comprising:
a plurality of sub chambers in which processes are performed on a substrate, respectively; and
a common exhaust part connected to the plurality of sub chambers to exhaust the inside of each of the plurality of sub chambers,
wherein each of the plurality of sub chambers comprises:
a substrate support on which the substrate is supported;
a shower head provided to face the substrate support and configured to supply a process gas toward the substrate;
an exhaust port provided below the substrate support and connected to the common exhaust part; and
a flow control part comprising a cover plate provided along a circumference of the substrate support, and configured to adjust an exhaust flow of the process gas to a lower portion of the substrate support.

2. The substrate processing apparatus of claim 1, wherein the plurality of sub chambers are disposed to be symmetrical to each other with respect to the common exhaust part.

3. The substrate processing apparatus of claim 2, wherein the exhaust port extends along the circumference of the substrate support.

4. The substrate processing apparatus of claim 1, wherein the cover plate is provided on at least a portion of the circumference of the substrate support to correspond to the exhaust port.

5. The substrate processing apparatus of claim 1, wherein the flow control part further comprises:
a movable plate stacked on the cover plate so as to be movable along a circumferential direction of the substrate support; and
a driver configured to move the movable plate on the cover plate.

6. The substrate processing apparatus of claim 5, wherein the driver is configured to move the movable plate so that an extension length of the cover plate and the movable plate in the circumferential direction of the substrate support varies.

7. The substrate processing apparatus of claim 5, wherein the cover plate comprises a through-part, and
the movable plate is configured to adjust an opened area of the cover plate through the through-part.

8. The substrate processing apparatus of claim 7, wherein the movable plate comprises an auxiliary through-part that is provided in shape or number different from that of the through-part.

9. The substrate processing apparatus of claim 5, wherein the cover plate is provided in the form of a ring or arc that surrounds at least a portion of the substrate support, and
the movable plate is provided in the form of an arc that is equal to or less than that of the cover plate.

10. The substrate processing apparatus of claim 1, wherein the common exhaust part comprises:
a plurality of individual exhaust lines, each of which communicates with the exhaust port of each of the plurality of sub chambers;
a combined exhaust line to which the plurality of individual exhaust line; and
a vacuum pump connected to the combined exhaust line.

11. The substrate processing apparatus of claim 1, further comprising a substrate transfer part configured to move the substrate between two adjacent sub chambers in a direction crossing a radial direction of the common exhaust part through a communication space between the plurality of sub chambers.

12. The substrate processing apparatus of claim 1, wherein each of the plurality of sub chambers further comprises:
a liner configured to define an exhaust space in a lower space within the sub chamber; and
an inner liner provided inside the liner to surround an outer surface of the substrate support,
wherein the cover plate is provided between the liner and the inner liner.

13. The substrate processing apparatus of claim 12, wherein an upper end of the inner liner is higher than an upper end of the liner.
